(19) United States
(12) Patent Application Publication
(10) Pub. No.: US 2026/0203995 A1
(43) Pub. Date: Jul. 16, 2026

(54) BUILDING FOR AUGMENTED REALITY OR MIXED REALITY, METHOD FOR DESIGNING BUILDING FOR AUGMENTED REALITY OR MIXED REALITY, INTERIOR DECORATION FOR AUGMENTED REALITY OR MIXED REALITY, METHOD FOR DESIGNING INTERIOR DECORATION FOR AUGMENTED REALITY OR MIXED REALITY, IMAGE CONTROL SYSTEM, IMAGE CONTROL PROGRAM, STORAGE MEDIUM HAVING IMAGE CONTROL PROGRAM RECORDED THEREIN, AND IMAGE CONTROL METHOD

(71) Applicant: STYLY, INC., Tokyo (JP)

(72) Inventor: Masahiro YAMAGUCHI, Tokyo (JP)

(21) Appl. No.: 19/137,167

(22) PCT Filed: Dec. 8, 2023
(86) PCT No.: PCT/JP2023/044095

§ 371 Date: Jun. 9, 2025

(30) Foreign Application Priority Data
Dec. 16, 2022 (JP) 2022-201437

(51) Int. Cl. G06T 15/10; E04H 3/22; G06F 30/13; G06T 19/00

(52) U.S. Cl. CPC G06T 15/10; E04H 3/22; G06F 30/13; G06T 19/006; G06T 2210/04

(57) ABSTRACT

A control unit that displays a reality image that is an image of a specific space, on a display while superimposing CG images CG1, CG2 on the reality image is provided; in at least a partial region of surfaces of a wall and a ceiling , a specific pattern is added so as to cover the region; and the control unit determines a region where the specific pattern is added in the reality image as an occlusion-off region, refrains from executing occlusion when superimposing the CG image CG1 on the occlusion-off region, and executes occlusion when superimposing the CG image CG2 on a region other than the occlusion-off region in the reality image.

### TECHNICAL FIELD

The present invention relates to a building for augmented reality or mixed reality, a method for designing a building for augmented reality or mixed reality, an interior decoration for augmented reality or mixed reality, a method for designing an interior decoration for augmented reality or mixed reality, an image control system, an image control program, a storage medium having an image control program recorded therein, and an image control method, for displaying augmented reality or mixed reality.

### BACKGROUND ART

Conventionally, in augmented reality (AR) or mixed reality (MR), occlusion has been known (for example, see Patent Literature (PTL) 1). In the occlusion, when a real object exists on the near side and a computer graphics (CG) object is located on the far side, the real object is drawn so as to be displayed on the near side relative to the CG on the far side.

### CITATION LIST

### Patent Literature

[PTL 1] Japanese Unexamined Patent Application Publication No. 2022-43909

### SUMMARY OF THE INVENTION

### Problems to be Solved by the Invention

In augmented reality or mixed reality, a CG content image may be superimposed on an actually captured reality image and then displayed. In such a case, if a content image that is larger than an interior space is displayed and occlusion is executed in a closed space such as indoors, a part of the content image penetrates the ceiling or wall of the interior space, and the part of the content image is hidden by the ceiling or wall.

It is an object of the present invention to provide a building for augmented reality or mixed reality capable of displaying a content image that is larger than an interior space, a method for designing the building for augmented reality or mixed reality, an interior decoration for augmented reality or mixed reality, a method for designing the interior decoration for augmented reality or mixed reality, an image control system, an image control program, and an image control program.

### Solution to the Problems

An image control system according to the present invention includes a control unit that displays, on a display, a reality image that is an image of a specific space having a wall and a ceiling, and is captured by a camera in a display terminal for augmented reality or mixed reality including the camera and the display, while superimposing a predetermined content image on the reality image. In an occlusion-off region that is at least a partial region of surfaces of the wall and the ceiling, a specific pattern that is preset to cover the occlusion-off region is added. The control unit determines a region where the specific pattern is added in the reality image as the occlusion-off region, refrains from executing occlusion when superimposing the content image on the occlusion-off region, and executes occlusion when superimposing the content image on a region other than the occlusion-off region in the reality image.

An image control method according to the present invention includes a mixed reality control step of displaying, on a display, a reality image that is an image of a specific space having a wall and a ceiling, and is captured by a camera in a display terminal for augmented reality or mixed reality including the camera and the display, while superimposing a predetermined content image on the reality image. In an occlusion-off region that is at least a partial region of surfaces of the wall and the ceiling, a specific pattern preset to cover the occlusion-off region is added. The mixed reality control step includes: determining a region where the specific pattern is added in the reality image as the occlusion-off region; refraining from executing occlusion when superimposing the content image on the occlusion-off region; and executing occlusion when superimposing the content image on a region other than the occlusion-off region in the reality image.

An image control system according to the present invention includes a control unit that displays, on a display, a reality image that is an image of a specific space having a wall and a ceiling, and is captured by a camera in a display terminal for augmented reality or mixed reality including the camera and the display, while superimposing a predetermined content image on the reality image. The control unit deletes a line corresponding to a corner of the specific space from the reality image without executing occlusion when superimposing the content image on the reality image.

An image control system according to the present invention includes a control unit that superimposes a predetermined content image, without executing occlusion, on a reality image that is an image of a specific space having a wall and a ceiling, and is captured by a camera in a display terminal for augmented reality or mixed reality including the camera and a display. The specific space has an inner surface that is plain.

According to these configurations, it is possible to display, in a specific space, a content image that is larger than the specific space.

Preferably, the control unit further deletes the specific pattern from the reality image.

According to the configuration, it is possible to generate an image that does not give a feeling of strangeness to a user by deleting the specific pattern that is not necessary for the user.

Preferably, the specific pattern is a pattern that differs depending on a position where the pattern is added in the occlusion-off region, and the control unit further specifies a relative position of the display terminal in the reality image with respect to the specific space from the specific pattern captured, and displays the content image in accordance with the specified relative position.

According to the configuration, the specific pattern is a pattern that differs depending on the position where the pattern is added in the occlusion-off region. Accordingly, it is possible to specify, on the basis of the specific pattern in the reality image, the relative position of the display terminal having captured the reality image, with respect to the specific space.

Preferably, the control unit further deletes a line corresponding to a corner of the specific space from the reality image.

According to the configuration, it is possible to reduce a feeling of strangeness caused by refraining from executing occlusion.

Preferably, the display terminal is further provided.

According to the configuration, the display terminal is included in the image control system.

Preferably, the control unit is incorporated in the display terminal.

According to the configuration, the display terminal functions as the control unit.

Preferably, the specific space is further provided.

According to the configuration, the specific space is included in the image control system.

A building for augmented reality or mixed reality according to the present invention includes the specific space for use in the aforementioned image control system.

The building for augmented reality or mixed reality constitutes the specific space for use in the aforementioned image control system.

A method for designing a building for augmented reality or mixed reality according to the present invention includes designing so as to add the specific pattern in at least a partial region of surfaces of the wall and the ceiling of the aforementioned building for augmented reality or mixed reality.

According to the designing method, it is possible to design a building for augmented reality or mixed reality.

In an interior decoration for augmented reality or mixed reality according to the present invention, the specific pattern is added in at least part of an inner surface of the specific space for use in the aforementioned image control system.

The interior decoration for augmented reality or mixed reality constitutes a specific space for use in the aforementioned image control system.

A method for designing an interior decoration for augmented reality or mixed reality according to the present invention includes designing so as to add the specific pattern in at least part of an inner surface of the aforementioned interior decoration for augmented reality or mixed reality.

According to the designing method, it is possible to design an interior decoration for augmented reality or mixed reality.

An image control program according to the present invention causes a computer to function as the control unit for use in the aforementioned image control system.

The image control program causes a computer to function as a control unit for use in the aforementioned image control system.

In a storage medium according to the present invention, the aforementioned image control program is recorded.

The storage medium has the aforementioned image control program recorded therein.

### Advantageous Effects of the Invention

The building for augmented reality or mixed reality, the method for designing a building for augmented reality or mixed reality, the interior decoration for augmented reality or mixed reality, the method for designing an interior decoration for augmented reality or mixed reality, the image control system, the image control program, the storage medium having the image control program recorded therein, and the image control method having the configurations described above make it possible to display a content image that is larger than the interior space.

### BRIEF DESCRIPTION OF THE DRAWINGS

FIG. 1 is a conceptual diagram showing one example of the configuration of an image control system according to an embodiment of the present invention.

FIG. 2 is a conceptual explanatory diagram for the positional relationship when three-dimensional CG images are placed in a specific space.

FIG. 3 is an explanatory diagram for a specific space, CG images, and a third party viewed by a user using a conventional display terminal in the state shown in FIG. 2.

FIG. 4 is an explanation diagram for an image when occlusion has not been executed in the state shown in FIG. 3.

FIG. 5 is a flowchart showing one example of the operation of the image control system.

FIG. 6 is an image showing one example of a reality image captured by a display terminal.

FIG. 7 is an explanatory diagram showing one example of a composite image G2 generated in step S5.

FIG. 8 is an explanatory diagram showing one example of a composite image G3 generated in step S6.

FIG. 9 is an explanatory diagram showing one example of a composite image G4 generated in step S7.

### DESCRIPTION OF EMBODIMENTS

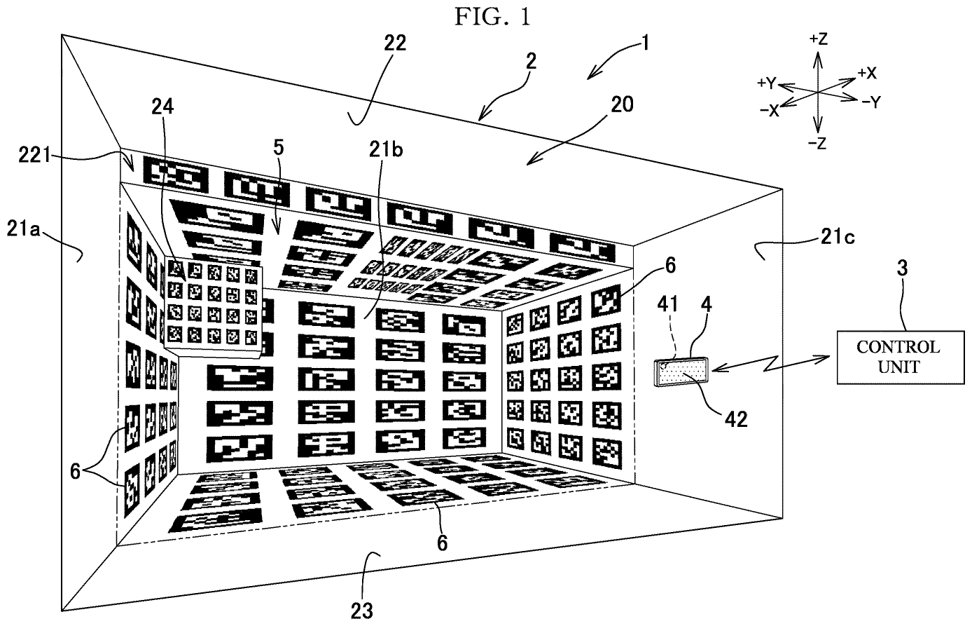

Hereinafter, an embodiment according to the present invention will be described on the basis of the drawings. The configuration denoted by the same reference character in each figure indicates the same configuration, and the description thereof is omitted. In each figure, XYZ orthogonal coordinate axes are appropriately shown so as to clarify the directional relationship. FIG. 1 is a conceptual diagram showing one example of the configuration of an image control system 1 according to an embodiment of the present invention. The image control system 1 includes a building 2, a display terminal 4, and a control unit 3.

The building 2 includes a specific space 20 having walls 21a, 21b, 21c, a ceiling 22, and a floor 23. The ceiling 22 is provided with a stepped portion 221. The building 2 has an interior decoration in which a specific pattern/specific patterns 6 that are preset so as to cover part of the walls 21a, 21c, the ceiling 22, and the floor 23 are added. The stepped portion 221 of the ceiling 22, and the entire surface of the wall 21b are covered with the specific pattern 6. The specific space 20 is provided with a protruding portion 24 whose entire surface is covered with the specific pattern 6. The protruding portion 24 protrudes from the walls 21a, 21b and the ceiling 22.

The image control system 1 need not necessarily include the display terminal 4, and need not necessarily include the building 2 and the specific space 20.

The region covered with the specific pattern 6 is referred to as an occlusion-off region 5. The specific pattern 6 differs depending on the position where the pattern is added in the occlusion-off region 5. As the specific pattern 6, various patterns such as a pattern known as a random dot pattern and an AR marker similar to a QR code (registered trademark) can be used.

As a method for designing the building 2, a method of designing the building 2 to be covered with the specific pattern in at least a partial region of surfaces of the walls and the ceiling can be used. As a method for designing the interior decoration of the specific space 20, a method of designing the specific space 20 to be covered with the specific pattern in at least part of the inner surface of the specific space 20 can be used.

The display terminal 4 is a terminal device including a camera 41 and a display 42. As the display terminal 4, a so-called smartphone, VR goggles with a camera such as a head-mounted display, so-called AR glasses, and the like can be used. The display terminal 4 is able to communicate with the control unit 3. The display terminal 4 may communicate with the control unit 3 by wireless communication such as WiFi (registered trademark), may communicate with the control unit 3 via mobile communication or the Internet, or may communicate with the control unit 3 by wired communication via a cable, for example.

The display terminal 4 transmits a reality image G1 captured by the camera 41 to the control unit 3, and displays an image in response to an instruction from the control unit 3 on the display 42.

The control unit 3 can be configured using a computer such as a server device or a game machine, for example. Alternatively, the control unit 3 may be incorporated in the display terminal 4.

The control unit 3 includes, for example, a central processing unit (CPU) that executes a predetermined arithmetic process, a random access memory (RAM) that temporarily stores data, a non-volatile storage device, a communication circuit, peripheral circuits thereof, and the like. The control unit 3 operates by, for example, executing an image control program stored in the aforementioned storage device.

The control unit 3 superimposes a predetermined content image on the reality image G1 that is an image of the specific space 20 captured by the camera 41 of the display terminal 4, and displays the resultant image on the display 42. The control unit 3 determines a region where the specific pattern 6 is added in the reality image G1 as the occlusion-off region 5, does not execute occlusion when superimposing the content image on the occlusion-off region 5, and executes occlusion when superimposing the content image on a region other than the occlusion-off region 5 in the reality image G1.

Next, before describing the operation of the image control system 1, a usage scene of mixed reality considered by the present inventor will be described. In the mixed reality, a user exists in a real space. Then, on a mixed reality device such as a smartphone or a head-mounted display, the CG image is superimposed on the reality image actually captured by the camera. Through the mixed reality device, the user will experience, so to say, a real space augmented by CG.

At this time, if it is possible to display a CG image that is larger than the real space size, for example, the size of the room in which the user is located, it is expected that the user can feel the expansion of the space, as if the real space has expanded.

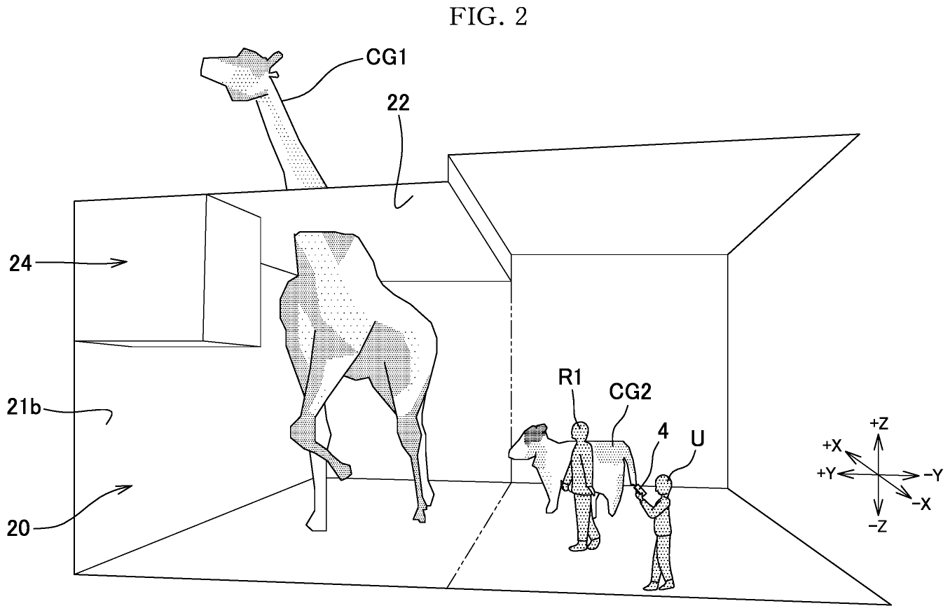

FIG. 2 is a conceptual explanatory diagram for the positional relationship when three-dimensional CG images CG1, CG2 are placed in the specific space 20. The CG image CG1 is a three-dimensional CG image of a giraffe that is larger than the specific space 20. When the CG image CG1 is placed in the specific space 20, the neck of the giraffe penetrates the ceiling 22 as shown in FIG. 2.

In the specific space 20, the three-dimensional CG image CG2 of a cow is placed in the −Y direction of the CG image CG1. In the −X direction of the CG image CG2, a real third party R1 is standing, and a user U is standing in the −X direction of the third party R1. The user U is viewing the specific space 20 via the display 42 using the display terminal 4.

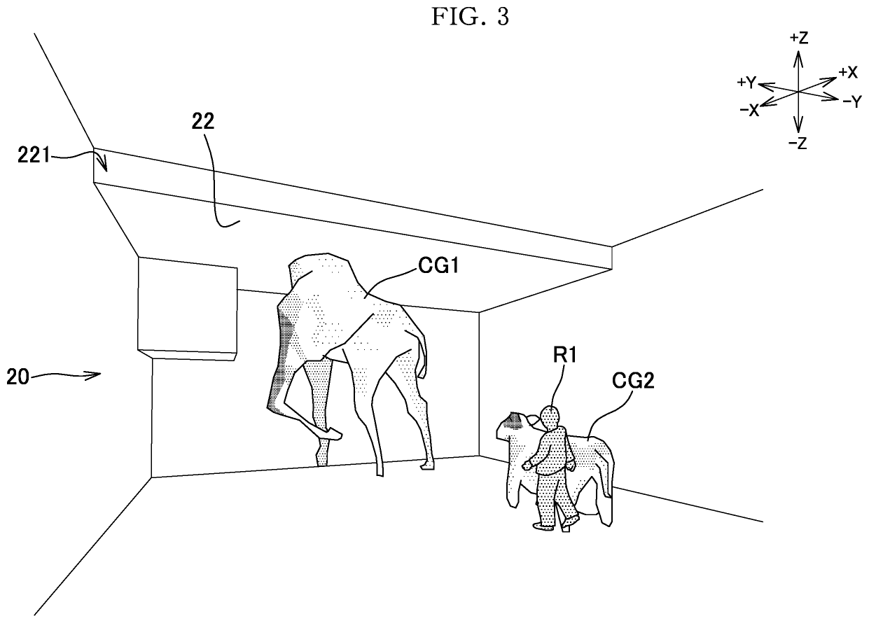

FIG. 3 is an explanatory diagram for the specific space 20, the CG images CG1, CG2, and the third party R1 viewed by the user U using a conventional display terminal in the state shown in FIG. 2. In this case, the walls, the ceiling, the floor, and the third party R1 in the specific space 20 are captured in an actually captured reality image, and the CG images CG1 and CG2 are superimposed on the reality image.

Then, in the display image on the conventional display terminal, the neck of the CG image CG1 of the giraffe penetrating the ceiling 22 is hidden behind the ceiling 22 due to occlusion. Further, since the CG image CG2 of the cow is placed on the far side relative to the third party R1, a part of the CG image CG2 is hidden behind the third party R1 due to occlusion.

Thus, when occlusion is executed using a conventional display terminal, it is impossible to display the entirety of the CG image that is larger than the specific space 20.

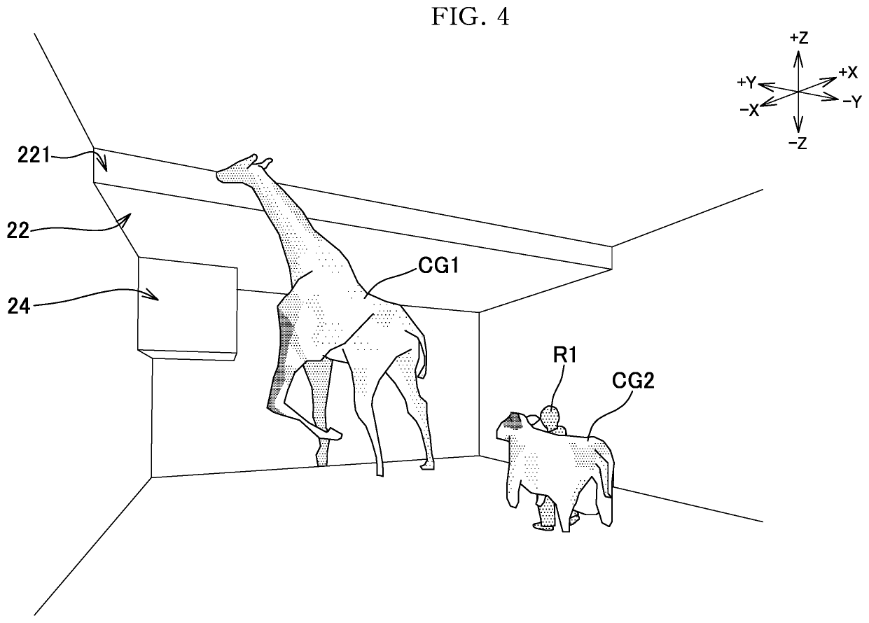

FIG. 4 is an explanatory diagram for an image when occlusion has not been executed in the state shown in FIG. 3. When occlusion is not executed, unlike FIG. 3, it is possible to display the entirety of the CG image CG1 of the giraffe. On the other hand, the CG image CG2 of the cow placed on the far side relative to the third party R1 is also displayed in its entirety, and the reality image of the third party R1 on the near side relative to the CG image CG2 is obscured by the CG image CG2.

Thus, when the user U moves while viewing the specific space 20 using a conventional display terminal in the state where the reality image of the third party R1 is obscured by the CG image CG2, the user U may collide with the third party R1 without noticing the existence of the third party R1. Therefore, even if the entirety of the CG image CG1 of the giraffe can be displayed, it is not preferable not to execute occlusion.

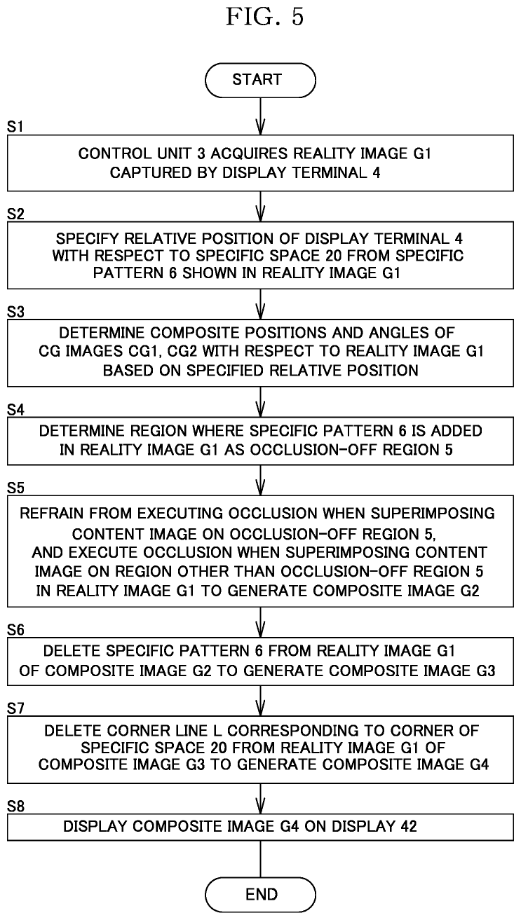

Hereinafter, the operation of the image control system 1 will be described. FIG. 5 is a flowchart showing one example of the operation of the image control system 1. As a premise, a case where the user U and the third party R1 are standing at the positions shown in FIG. 2 with respect to the specific space 20 shown in FIG. 1 is described as an example.

First, the user U photographs the specific space 20 shown in FIG. 1 with the camera of the display terminal 4. Then, the reality image G1 captured by the display terminal 4 is acquired by the control unit 3 (step S1).

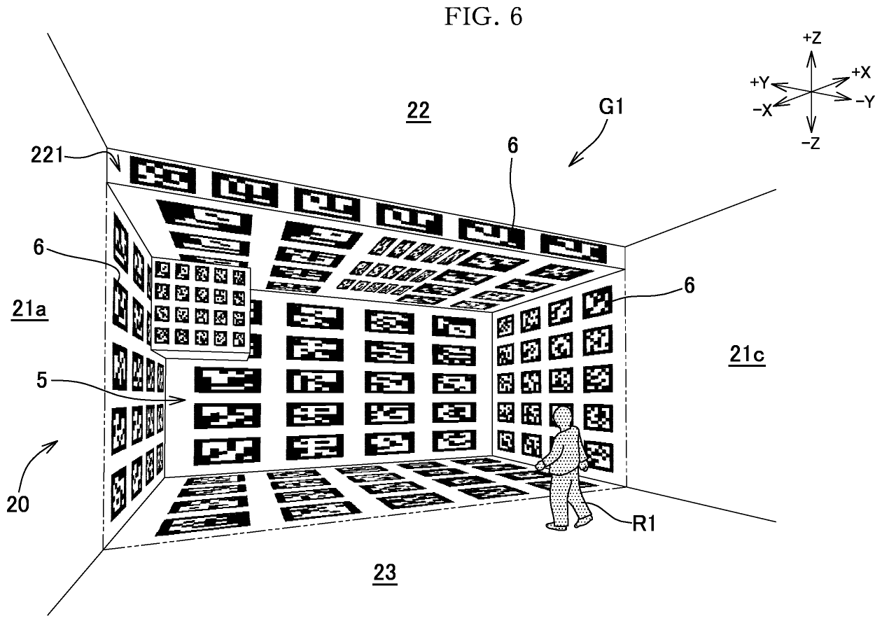

FIG. 6 is an image showing one example of the reality image G1 captured by the display terminal 4. In the reality image G1, only the actually existing specific space 20 and the appearance of the third party R1 are shown.

Next, the control unit 3 specifies the relative position of the display terminal 4 with respect to the specific space 20 from the specific pattern 6 in the reality image G1 (step S2). Since the specific pattern 6 is a pattern that differs depending on the position where the pattern is added in the occlusion-off region 5, it becomes possible to specify, on the basis of the specific pattern 6 in the reality image G1, the relative position of the display terminal 4 having captured the reality image G1 with respect to the specific space 20.

Note that it is not limited to the example in which the relative position of the display terminal 4 with respect to the specific space 20 is specified on the basis of the specific pattern 6. As a method for specifying the relative position of the display terminal 4 with respect to the specific space 20, various known methods can be employed.

Next, the control unit 3 determines composite positions and angles of the CG images CG1, CG2 with respect to the reality image G1 on the basis of the relative position specified in step S2 (step S3). The CG images CG1, CG2 correspond to one example of a content image. As one example of a content image, a giraffe and a cow are shown, but the content image is not limited to a specific image. The content image may be, for example, a starry sky, a city view, or the like.

Next, the control unit 3 determines a region in which the specific pattern 6 is added in the reality image G1 as the occlusion-off region 5 (step S4).

Next, the control unit 3 does not execute occlusion when superimposing the content image on the occlusion-off region 5, and executes occlusion when superimposing the content image on a region other than the occlusion-off region 5 in the reality image G1, to generate a composite image G2 (step S5). In step S5, the control unit 3 composites the CG images CG1, CG2, which are content images, with the reality image G1 on the basis of the composite positions and angles determined in step S3, to generate the composite image G2.

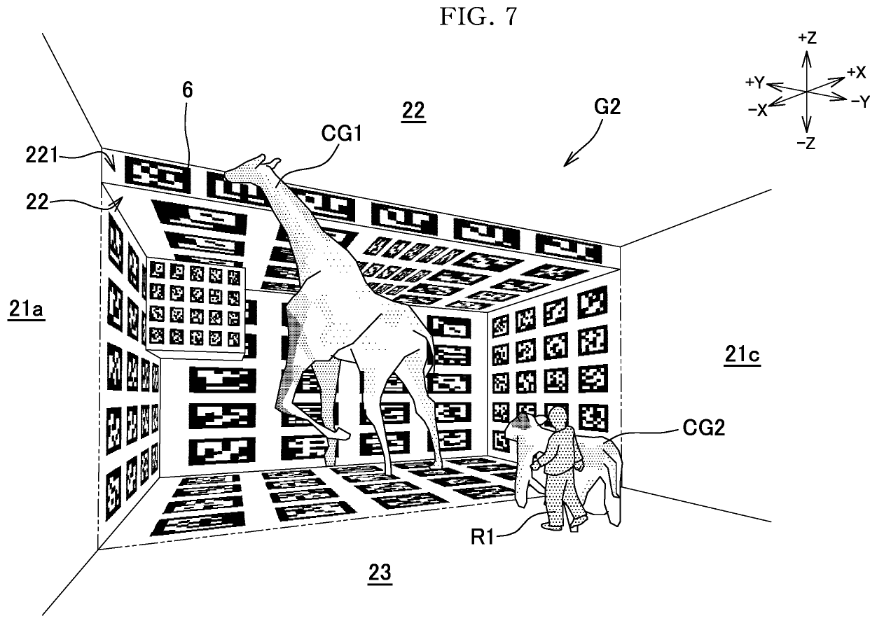

FIG. 7 is an explanatory diagram showing one example of the composite image G2 generated in step S5. The CG image CG1 of the giraffe is superimposed on the occlusion-off region 5 covered with the specific pattern 6. Therefore, in step S7, occlusion is not executed, and the entirety of the CG image CG1 is displayed unlike FIG. 3 though the CG image CG1 of giraffe is larger than the specific space 20.

Thus, according to the composite image G2 in which the CG image CG1 that is larger than the real space size is displayed, it is possible to make the user U using the display terminal 4 feel the expansion of the space, as if the real space has expanded.

On the other hand, the CG image CG2 of the cow is superimposed on the reality image of the third party R1. Since the specific pattern 6 is not added in the image of the third party R1, the third party R1 corresponds to a region other than the occlusion-off region 5 in step S5. Therefore, the CG image CG2 of the cow is superimposed on the image of the third party R1, which corresponds to a region other than the occlusion-off region 5, by executing occlusion. As a result, the image of the third party R1 is not obscured by the CG image CG2 of the cow, and even when the user U moves while viewing the specific space 20 using the display terminal 4, the risk that the user U may collide with the third party R1 without noticing the existence of the third party R1 is reduced, unlike the case shown in FIG. 4.

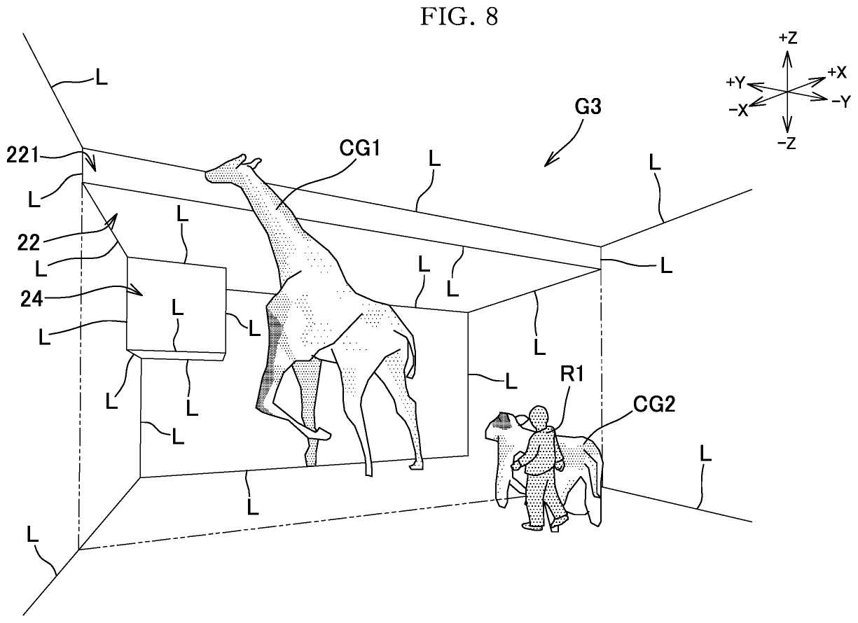

Next, the control unit 3 deletes the specific pattern 6 from the reality image G1 part of the composite image G2, to generate a composite image G3 (step S6). FIG. 8 is an explanatory diagram showing one example of the composite image G3 generated in step S6.

In the image control system 1, the specific pattern 6 added to the walls 21a, 21b, 21c, the ceiling 22, the floor 23, and the protruding portion 24 enables both display of the CG image CG1 that, is a content image larger than the interior space, and reduction of the risk that the user U may collide with the third party R1 or the like. However, the specific pattern 6 is not necessary for the user U. Therefore, the specific pattern 6 is deleted from the composite image G2, thereby generating the composite image G3 that can be easily viewed by the user U.

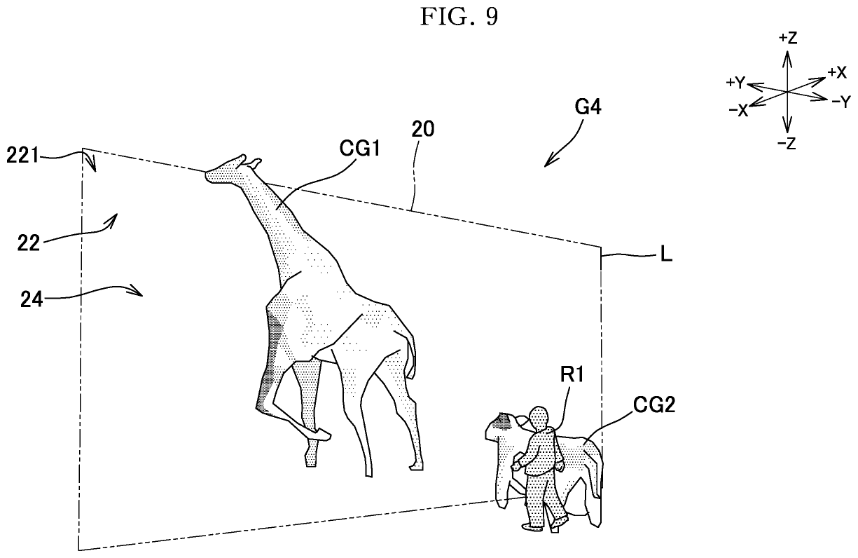

Next, the control unit 3 deletes corner lines L, which are lines corresponding to corners of the specific space 20, from the reality image G1 part of the composite image G3, to generate a composite image G4 (step S7). FIG. 9 is an explanatory diagram showing one example of the composite image G4 generated in step S7.

In the composite image G3 shown in FIG. 8, the CG image CG1 that is larger than the interior space can be displayed. However, the neck of the giraffe that should be on the far side relative to the stepped portion 221 is displayed on the near side relative to the stepped portion 221. This is inconsistent with perspective, and gives a feeling of strangeness as if the space were distorted. Therefore, the corner lines L are deleted from the composite image G3, preventing the distortion of the space from being felt, and the feeling of strangeness can be reduced, as in the composite image G4 shown in FIG. 9.

Next, the control unit 3 displays the composite image G4 on the display 42 of the display terminal 4 (step S8). As a result, by viewing the specific space 20 via the display terminal 4, the user U can experience the sense of mixed reality in which the specific space 20 is expanded and the CG image CG1 is displayed without feeling of strangeness, and the risk that the user U may collide with the third party R1 or the like can be reduced.

Note that the control unit 3 may display the composite image G3 in step S8 without executing step S7, and may display the composite image G2 in step S8 without executing steps S6 and S7. Further, the control unit 3 may process the composite image G2 in step S7 without executing step S6.

Further, the specific pattern 6 need not necessarily be a pattern that differs depending on the position where the pattern is added in the occlusion-off region 5, and the control unit 3 need not necessarily execute steps S2 and S3.

Further, the specific pattern 6 need not necessarily be added to the specific space 20, and the control unit 3 need not necessarily execute steps S2 to S4, and S6, and may superimpose a content image on the reality image G1 without executing occlusion constantly in step S5. Even in the case where the occlusion is constantly executed in step S5, the corner lines L are deleted in step S7, thereby reducing the feeling of strangeness as if the space were distorted while displaying the content image that is larger than the interior space.

Further, the inner surface of the specific space 20 may be plain, and steps S2 to S4, S6 may not be executed. In such a situation, the control unit 3 may superimpose the content image on the reality image G1 without executing occlusion constantly, to generate the composite image G2 in step S5, and may process the composite image G2 in step S7. Alternatively, the composite image G2 may be displayed in step S8, without executing step S7.

The occlusion may not be executed constantly in step S5. Even in such a case, if the inner surface of the specific space 20 is plain, the user U is less likely to perceive a sense of perspective from the composite image G4 displayed on the display 42. Therefore, it is possible to reduce the feeling of strangeness as if the space were distorted while displaying the content image that is larger than the interior space.

### DESCRIPTION OF THE REFERENCE CHARACTERS

1 image control system
2 building
3 control unit
4 display terminal
5 occlusion-off region
6 specific pattern
20 specific space
21a, 21b, 21c wall
22 ceiling
23 floor
24 protruding portion
41 camera
42 display
221 stepped portion
CG1, CG2 CG image (content image)
G1 reality image
G2, G3, G4 composite image
L corner line
R1 third party
U user

1. An image control system comprising:
a control unit that displays, on a display, a reality image that is an image of a specific space having a wall and a ceiling, and is captured by a camera in a display terminal for augmented reality or mixed reality including the camera and the display, while superimposing a predetermined content image on the reality image, wherein
in an occlusion-off region that is at least a partial region of surfaces of the wall and the ceiling, a specific pattern that is preset to cover the occlusion-off region is added, and
the control unit determines a region where the specific pattern is added in the reality image as the occlusion-off region, refrains from executing occlusion when superimposing the content image on the occlusion-off region, and executes occlusion when superimposing the content image on a region other than the occlusion-off region in the reality image.

2. The image control system according to claim 1, wherein
the control unit further deletes the specific pattern from the reality image.

3. The image control system according to claim 1, wherein
the specific pattern is a pattern that differs depending on a position where the pattern is added in the occlusion-off region, and
the control unit further specifies a relative position of the display terminal in the reality image with respect to the specific space from the specific pattern captured, and displays the content image in accordance with the specified relative position.

4. The image control system according to claim 1, wherein
the control unit further deletes a line corresponding to a corner of the specific space from the reality image.

5. An image control system comprising
a control unit that displays, on a display, a reality image that is an image of a specific space having a wall and a ceiling, and is captured by a camera in a display terminal for augmented reality or mixed reality including the camera and the display, while superimposing a predetermined content image on the reality image, wherein
the control unit deletes a line corresponding to a corner of the specific space from the reality image without executing occlusion when superimposing the content image on the reality image.

6. An image control system comprising
a control unit that superimposes a predetermined content image, without executing occlusion, on a reality image that is an image of a specific space having a wall and a ceiling, and is captured by a camera in a display terminal for augmented reality or mixed reality including the camera and a display, wherein
the specific space has an inner surface that is plain.

7. The image control system according to claim 1, further comprising:
the display terminal.

8. The image control system according to claim 7, wherein
the control unit is incorporated in the display terminal.

9. The image control system according to claim 1, further comprising:
the specific space.

10. A building for augmented reality or mixed reality, comprising:
the specific space for use in the image control system according to claim 1.

11. A method for designing a building for augmented reality or mixed reality, comprising:
designing so as to add the specific pattern in at least a partial region of surfaces of the wall and the ceiling of the building for augmented reality or mixed reality according to claim 10.

12. An interior decoration for augmented reality or mixed reality, wherein
the specific pattern is added in at least part of an inner surface of the specific space for use in the image control system according to claim 1.

13. A method for designing an interior decoration for augmented reality or mixed reality, the method comprising:
designing so as to add the specific pattern in at least part of an inner surface of the interior decoration for augmented reality or mixed reality according to claim 12.

14. A storage medium having an image control program recorded therein, the image control program causing a computer to function as the control unit for use in the image control system according to claim 1.

15. (canceled)

16. An image control method comprising:
a mixed reality control step of displaying, on a display, a reality image that is an image of a specific space having a wall and a ceiling, and is captured by a camera in a display terminal for augmented reality or mixed reality including the camera and the display, while superimposing a predetermined content image on the reality image, wherein
in an occlusion-off region that is at least a partial region of surfaces of the wall and the ceiling, a specific pattern preset to cover the occlusion-off region is added, and
the mixed reality control step includes
determining a region where the specific pattern is added in the reality image as the occlusion-off region,
refraining from executing occlusion when superimposing the content image on the occlusion-off region, and
executing occlusion when superimposing the content image on a region other than the occlusion-off region in the reality image.
